(19) United States
(12) Patent Application Publication
(10) Pub. No.: US 2006/0223270 A1
(43) Pub. Date: Oct. 5, 2006

(54) Method of manufacturing semiconductor device

(75) Inventor: Toshiki Hara, Suwa-shi (JP)

Correspondence Address: EDWARDS & ANGELL, LLP, P.O. BOX 55874, BOSTON, MA, 02205, US

(73) Assignee: Seiko Epson Corporation, Tokyo (JP)

(21) Appl. No.: 11/393,186

(22) Filed: Mar. 29, 2006

(30) Foreign Application Priority Data
Mar. 29, 2005 (JP) 2005-094775

(51) Int. Cl. H01L 21/336; H01L 21/8222; H01L 21/331

(52) U.S. Cl. 438/294; 438/311

(57) ABSTRACT

A method of manufacturing a semiconductor device including a step of forming an insulating film on a semiconductor substrate, a step of removing the insulating film selectively in a first alignment mark forming region and a silicon-on-insulator (SOI) structure forming region that are provided on the semiconductor substrate by patterning the insulating film, a step of forming a first semiconductor layer selectively in the first alignment mark forming region and the SOI structure forming region by epitaxial growth, a step of forming a second semiconductor layer whose etching rate is smaller than an etching rate of the first semiconductor layer selectively on the first semiconductor layer by the epitaxial growth, and removing the insulating film on the semiconductor substrate after the second semiconductor layer is formed. The method further including a step of forming a first exposure part and a second alignment mark by selectively etching the second semiconductor layer, the first semiconductor layer and the semiconductor substrate as referring the position of the second semiconductor layer in the first alignment mark forming region as a first alignment mark for arrangement, the first exposure part penetrating the second semiconductor layer and the first semiconductor layer so as to expose the semiconductor substrate, and the second alignment mark being formed in a second alignment mark forming region on the semiconductor substrate, a step of forming a supporter made of a material with a smaller etching rate than the etching rate of the first semiconductor layer, the supporter supporting the second semiconductor layer on the semiconductor substrate through the first exposure part, a step of forming a second exposure part by referring the second alignment mark as a reference point for arrangement after the supporter is formed, the second exposure part exposing the first semiconductor layer, a step of forming a hollow part between the semiconductor substrate and the second semiconductor layer by selectively etching the first semiconductor layer through the second exposure part, the hollow part being made by removing the first semiconductor layer, a step of forming a buried insulating layer that fills the hollow part, a step of forming a first gate electrode by referring the second alignment mark as the reference point for arrangement, the first gate electrode being provided on the second semiconductor layer through a first gate insulating film, and a step of forming a first source/drain layer that is arranged so as to hold the first gate electrode therebetween in the second semiconductor layer.

### BACKGROUND OF THE INVENTION

1. Technical Field

The present invention relates to a method of manufacturing a semiconductor device, and more particularly, manufacturing a field effect transistor (FET) formed on a Silicon-On-Insulator (SOI) substrate.

2. Related Art

JP-A-2002-299591 is a first example of related art and JP-A-2000-124092 is a second example of related art. A field effect transistor formed on the SOI substrate has attracted attention for its availability because it has advantages such as easiness in device isolation, latch-up free and a small source-drain junction capacitance. Especially, a fully depleted SOI transistor consumes low power and can operate in high speed. In addition, the fully depleted SOI transistor can be easily driven with a small voltage. For this reason, there have been a lot of researches done recently for seeking a way to operate the SOI transistor in a fully depleted mode. As the SOI substrate, a Separation by Implanted Oxygen (SIMOX) substrate, a bonded substrate and the like are used in the first and second examples.

T. Sakai et al. “Separation by Bonding Si Islands (SBSI) for LSI Application”, Second International SiGe Technology and Device Meeting, Meeting Abstract, May 2004, Pages: 230-231 is a third example of related art. The third example discloses a method to manufacture the SOI transistor at a low cost by forming a SOI layer on a bulk substrate. According to the method disclosed in the third example, a Si/SiGe layer is formed on a Si substrate, and only the SiGe layer is selectively removed by utilizing difference in the selectivity of Si and SiGe. This makes a hollow part between the Si substrate and the Si layer. A SiO₂ layer is then embedded between the Si substrate and the Si layer by thermally oxidizing Si which is exposed in the hollow part. In this way, a buried oxide (BOX) layer is formed between the Si substrate and the Si layer.

According to the method disclosed in the third example, both the SOI transistor and the bulk transistor can be simultaneously formed in a wafer. In this case, the SiGe layer is not formed on the whole surface of the wafer but formed only in the SOI transistor forming region by selective epitaxial growth. In the case that the SiGe layer is formed in the SOI transistor forming region by the selective epitaxial growth, an alignment mark for mask alignment is also formed by the selective epitaxial growth for forming the SiGe layer. The mask alignment is going to take place in a later process against the SOI transistor forming region. The position of the device formed in the SOI transistor forming region can be specified by the mask alignment against the SOI transistor forming region with reference to the alignment mark.

However, when the alignment mark that specifies the SOI transistor region is referred through all the processes after the formation of the SOI transistor forming region (a body ion implantation process, a gate electrode forming process, ion implantation into a diffused layer, a contact hole forming process and the like), misalignment tends to occur and this deteriorates the alignment accuracy of the device.

### SUMMARY

An advantage of the invention is to provide a method of manufacturing a semiconductor device with which the SOI structure can be selectively formed on the bulk substrate and the alignment accuracy of the device can be improved at the same time.

According to a first aspect of the invention, a method of manufacturing a semiconductor device includes a step of forming an insulating film on a semiconductor substrate, a step of removing the insulating film selectively in a first alignment mark forming region and a silicon-on-insulator (SOI) structure forming region that are provided on the semiconductor substrate by patterning the insulating film, a step of forming a first semiconductor layer selectively in the first alignment mark forming region and the SOI structure forming region by epitaxial growth, a step of forming a second semiconductor layer whose etching rate is smaller than an etching rate of the first semiconductor layer selectively on the first semiconductor layer by the epitaxial growth, and removing the insulating film on the semiconductor substrate after the second semiconductor layer is formed. The method further includes a step of forming a first exposure part and a second alignment mark by selectively etching the second semiconductor layer, the first semiconductor layer and the semiconductor substrate as referring the position of the second semiconductor layer in the first alignment mark forming region as a first alignment mark for arrangement, the first exposure part penetrating the second semiconductor layer and the first semiconductor layer so as to expose the semiconductor substrate, and the second alignment mark being formed in a second alignment mark forming region on the semiconductor substrate, a step of forming a supporter made of a material with a smaller etching rate than the etching rate of the first semiconductor layer, the supporter supporting the second semiconductor layer on the semiconductor substrate through the first exposure part, a step of forming a second exposure part by referring the second alignment mark as a reference point for arrangement after the supporter is formed, the second exposure part exposing the first semiconductor layer, a step of forming a hollow part between the semiconductor substrate and the second semiconductor layer by selectively etching the first semiconductor layer through the second exposure part, the hollow part being made by removing the first semiconductor layer, a step of forming a buried insulating layer that fills the hollow part, a step of forming a first gate electrode by referring the second alignment mark as the reference point for arrangement, the first gate electrode being provided on the second semiconductor layer through a first gate insulating film, and a step of forming a first source/drain layer that is arranged so as to hold the first gate electrode therebetween in the second semiconductor layer.

In this way, it is possible to place the first exposure part in the SOI structure forming region with reference to the position of the first alignment mark that specifies the position of the SOI structure forming region. Accordingly, the first exposure part is precisely arranged in the SOI structure forming region. Furthermore, it is possible to arrange the second exposure part with reference to the position of the second alignment mark that specifies the position of the first exposure part. Thereby, the second exposure part can be accurately arranged against the first exposure part. In addition, the device can be further formed with reference to the position of the second alignment mark as a reference point for the alignment in the later processes. Therefore, even after the SOI structure forming region is formed, the device can be arranged in the SOI structure forming region without referring the first alignment mark that specifies the position of the SOI structure forming region. Consequently, the accuracy of the device alignment is improved.

According to a second aspect of the invention, a method of manufacturing a semiconductor device includes a step of forming an insulating film on a semiconductor substrate, a step of removing the insulating film selectively in a first alignment mark forming region and a silicon-on-insulator (SOI) structure forming region that are provided on the semiconductor substrate by patterning the insulating film, a step of forming a first semiconductor layer selectively in the first alignment mark forming region and the SOI structure forming region by epitaxial growth, a step of forming a second semiconductor layer whose etching rate is smaller than an etching rate of the first semiconductor layer selectively on the first semiconductor layer by the epitaxial growth, a step of removing the insulating film on the semiconductor substrate after the second semiconductor layer is formed, a step of forming a first exposure part by selectively etching the second semiconductor layer in the SOI structure forming region, the first semiconductor layer and the semiconductor substrate, the first exposure part penetrating the second semiconductor layer and the first semiconductor layer so as to expose the semiconductor substrate, and a step of forming a supporter made of a material with a smaller etching rate than the etching rate of the first semiconductor layer, the supporter supporting the second semiconductor layer on the semiconductor substrate through the first exposure part. The method further includes a step of forming a second exposure part and a second alignment mark by selectively etching the supporter, the second semiconductor layer, the first semiconductor layer and the semiconductor substrate as referring the position of the second semiconductor layer in the first alignment mark forming region as a first alignment mark for arrangement after the supporter is formed, the second exposure part exposing the first semiconductor layer, and the second alignment mark being formed in a second alignment mark forming region on the semiconductor substrate, a step of forming a hollow part between the semiconductor substrate and the second semiconductor layer by selectively etching the first semiconductor layer through the second exposure part, the hollow part being made by removing the first semiconductor layer, a step of forming a buried insulating layer that fills the hollow part, a step of forming a first gate electrode by referring the second alignment mark as the reference point for arrangement, the first gate electrode being provided on the second semiconductor layer through a first gate insulating film, and a step of forming a first source/drain layer that is arranged so as to hold the first gate electrode therebetween in the second semiconductor layer.

In this way, it is possible to place the first exposure part and the second exposure part in the SOI structure forming region with reference to the position of the first alignment mark that specifies the position of the SOI structure forming region. Accordingly, the first exposure part and the second exposure part are precisely arranged in the SOI structure forming region. In addition, the device can be further formed with reference to the second alignment mark specifying the position of the second exposure part as a reference point for the alignment in the later processes. Therefore, even after the SOI structure forming region is formed, the device can be arranged in the SOI structure forming region without referring the first alignment mark that specifies the position of the SOI structure forming region. Consequently, the accuracy of the device alignment is improved.

According to a third aspect of the invention, a method of manufacturing a semiconductor device includes a step of forming an insulating film on a semiconductor substrate, a step of removing the insulating film selectively in a first alignment mark forming region and a silicon-on-insulator (SOI) structure forming region that are provided on the semiconductor substrate by patterning the insulating film, a step of forming a first semiconductor layer selectively in the first alignment mark forming region and the SOI structure forming region by epitaxial growth, a step of forming a second semiconductor layer whose etching rate is smaller than an etching rate of the first semiconductor layer selectively on the first semiconductor layer by the epitaxial growth, a step of removing the insulating film on the semiconductor substrate after the second semiconductor layer is formed, a step of forming a first exposure part and a second alignment mark by selectively etching the second semiconductor layer, the first semiconductor layer and the semiconductor substrate as referring the position of the second semiconductor layer in the first alignment mark forming region as a first alignment mark for arrangement, the first exposure part penetrating the second semiconductor layer and the first semiconductor layer so as to expose the semiconductor substrate, and the second alignment mark being formed in a second alignment mark forming region on the semiconductor substrate, and a step of forming a supporter made of a material with a smaller etching rate than the etching rate of the first semiconductor layer, the supporter supporting the second semiconductor layer on the semiconductor substrate through the first exposure part. The method further includes a step of forming a second exposure part and a third alignment mark by selectively etching the supporter, the second semiconductor layer, the first semiconductor layer and the semiconductor substrate as referring the position of the second alignment mark for arrangement after the supporter is formed, the second exposure part exposing the first semiconductor layer, and the third alignment mark being formed in a third alignment mark forming region on the semiconductor substrate, a step of forming a hollow part between the semiconductor substrate and the second semiconductor layer by selectively etching the first semiconductor layer through the second exposure part, the hollow part being made by removing the first semiconductor layer, a step of forming a buried insulating layer that fills the hollow part, a step of forming a first gate electrode by referring the third alignment mark as the reference point for arrangement, the first gate electrode being provided on the second semiconductor layer through a first gate insulating film, and a step of forming a first source/drain layer that is arranged so as to hold the first gate electrode therebetween in the second semiconductor layer.

In this way, it is possible to place the first exposure part in the SOI structure forming region with reference to the position of the first alignment mark that specifies the position of the SOI structure forming region. Accordingly, the first exposure part is precisely arranged in the SOI structure forming region. Furthermore, it is possible to arrange the second exposure part with reference to the position of the second alignment mark that specifies the position of the first exposure part. Thereby, the second exposure part can be accurately arranged against the first exposure part. In addition, the device can be further formed with reference to the third alignment mark specifying the position of the second exposure part as a reference point for the alignment in the later processes. Therefore, even after the SOI structure forming region is formed, the device can be arranged in the SOI structure forming region without referring the first alignment mark that specifies the position of the SOI structure forming region. Consequently, the accuracy of the device alignment is improved.

In these cases, the method may further include a step of forming a second gate electrode in a bulk structure forming region on the semiconductor substrate through a second gate insulating film, and a step of forming a second source/drain layer that is arranged so as to hold the second gate electrode therebetween in the second semiconductor layer.

In this way, the SOI structure can be formed on a part of the semiconductor substrate and the bulk structure can be simultaneously formed on the other part of the semiconductor substrate while reducing the chance of defects occurring in the second semiconductor layer. Therefore, both the SOI structure and the bulk structure can be formed on the same semiconductor substrate without using the SOI substrate. This can prevent cost increase and allows that both the SOI transistor and a transistor with a high withstand voltage are mounted on the one semiconductor substrate.

### BRIEF DESCRIPTION OF THE DRAWINGS

The invention will be described with reference to the accompanying drawings, wherein like numbers reference like elements.

FIG. 1 is a first drawing showing a method of manufacturing a semiconductor device according to a first embodiment of the invention.

FIG. 2 is a second drawing showing the method of manufacturing a semiconductor device according to the first embodiment of the invention.

FIG. 3 is a third drawing showing the method of manufacturing a semiconductor device according to the first embodiment of the invention.

FIG. 4 is a forth drawing showing the method of manufacturing a semiconductor device according to the first embodiment of the invention.

FIG. 5 is a fifth drawing showing the method of manufacturing a semiconductor device according to the first embodiment of the invention.

FIG. 6 is a sixth drawing showing the method of manufacturing a semiconductor device according to the first embodiment of the invention.

FIG. 7 is a seventh drawing showing the method of manufacturing a semiconductor device according to the first embodiment of the invention.

FIG. 8 is an eighth drawing showing the method of manufacturing a semiconductor device according to the first embodiment of the invention.

FIG. 9 is a first drawing showing a method of manufacturing a semiconductor device according to a second embodiment of the invention.

FIG. 10 is a second drawing showing the method of manufacturing a semiconductor device according to the second embodiment of the invention.

FIG. 11 is a third drawing showing the method of manufacturing a semiconductor device according to the second embodiment of the invention.

FIG. 12 is a forth drawing showing the method of manufacturing a semiconductor device according to the second embodiment of the invention.

FIG. 13 is a fifth drawing showing the method of manufacturing a semiconductor device according to the second embodiment of the invention.

### DESCRIPTION OF THE EMBODIMENTS

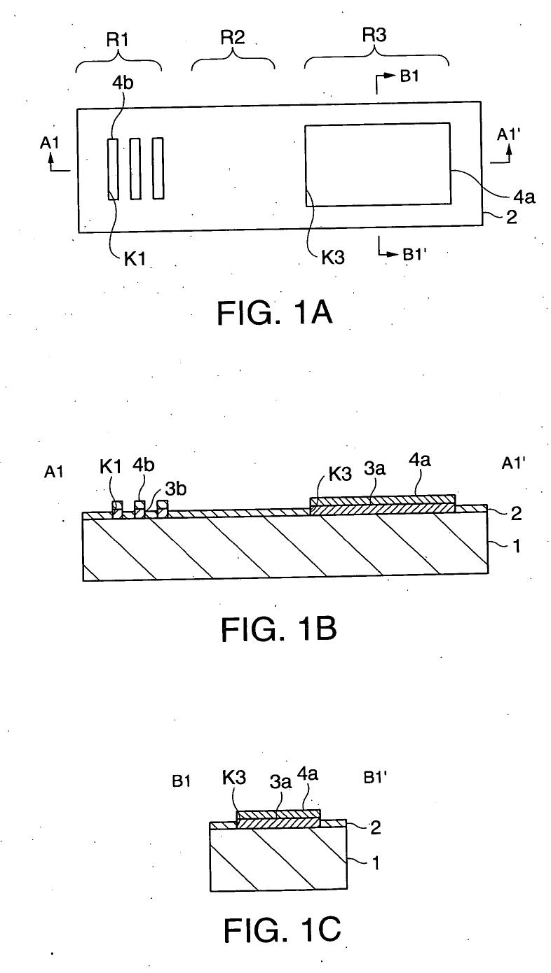

FIGS. 1A to 8A are plan views showing a method of manufacturing a semiconductor device according to a first embodiment of the invention. FIGS. 1B to 8B are sectional views along the lines A1 to A1′ through A8 to A8′ in FIGS. 1A to 8A. FIGS. 1C to 8C are sectional views along the lines B1 to B1′ through B8 to B8′ in FIGS. 1A to 8A.

As shown in FIG. 1, a first alignment mark forming region R1 for making a first alignment mark, a second alignment mark forming region R2 for making a second alignment mark and a SOI structure forming region R3 for making a SOI structure are provided on a semiconductor substrate 1. An oxide film 2 is formed on the whole surface of the semiconductor substrate 1 by an oxidation method such as thermal oxidation. An opening K1 for arranging the first alignment mark in the first alignment mark forming region R1 is formed by patterning the oxide film 2 by using photolithography or etching technique. At the same time, an opening K3 for disposing the SOI structure in the SOI structure forming region R3 is also formed by patterning the oxide film 2. Subsequently, a first semiconductor layer 3a and a second semiconductor layer 4a are sequentially formed in the SOI structure forming region R3 by the selective epitaxial growth. At the same time, a first semiconductor layer 3b and a second semiconductor layer 4b are sequentially formed in the first alignment mark forming region R1.

In the selective epitaxial growth, material gases for forming the first semiconductor layers 3a, 3b and the second semiconductor layers 4a, 4b are provided and the first semiconductor layers 3a, 3b and the second semiconductor layers 4a, 4b are formed by thermal chemical vapor deposition (CVD). In this way, the first semiconductor layers 3a, 3b and the second semiconductor layers 4a, 4b, which are single crystal semiconductor layers, are formed on the semiconductor substrate 1 that is exposed through the openings K1, K3. Here, an amorphous semiconductor layer will be formed on the oxide film 2 at the time of forming the single crystal semiconductor layer on the semiconductor substrate. However, the amorphous semiconductor layer can be broke down and removed by exposing the amorphous semiconductor layer to a chlorine gas while remaining the single crystal semiconductor layer on the semiconductor substrate 1. Therefore, it is possible to form the first semiconductor layers 3a, 3b and the second semiconductor layers 4a, 4b on the semiconductor substrate 1 through the openings K1, K3 by the selective epitaxial growth.

For the first semiconductor layers 3a and 3b, a material having a larger etching late than that of the semiconductor substrate 1 and the second semiconductor layers 4a, 4b can be used. As for the material for forming the semiconductor substrate 1, the first semiconductor layers 3a, 3b and the second semiconductor layers 4a, 4b, for example, a combination selected from the following materials such as Si, Ge, SiGe, SiC, SiSn, PbS, GaAs, InP, GaP, GaN and ZnSe can be used. Especially when the semiconductor substrate 1 is made of Si, it is preferable that the first semiconductor layers 3a, 3b are made of SiGe and the second semiconductor layers 4a, 4b are made of Si. In this way, the lattice of the first semiconductor layers 3a, 3b can be matched with the lattice of the second semiconductor layers 4a, 4b, securing the selectivity between the first semiconductor layers 3a, 3b and the second semiconductor layers 4a, 4b. Besides the single crystal semiconductor layer, a polycrystalline semiconductor layer, an amorphous semiconductor layer and a porous semiconductor layer can also be used for the first semiconductor layers 3a, 3b. Furthermore, a metal oxide film which can be formed by the epitaxial growth such as γ-alumina may be used instead of the first semiconductor layers 3a, 3b which are the single crystal semiconductor layer. Thickness of the first semiconductor layers 3a, 3b and the second semiconductor layers 4a, 4b is, for example, may be 1-100 nm.

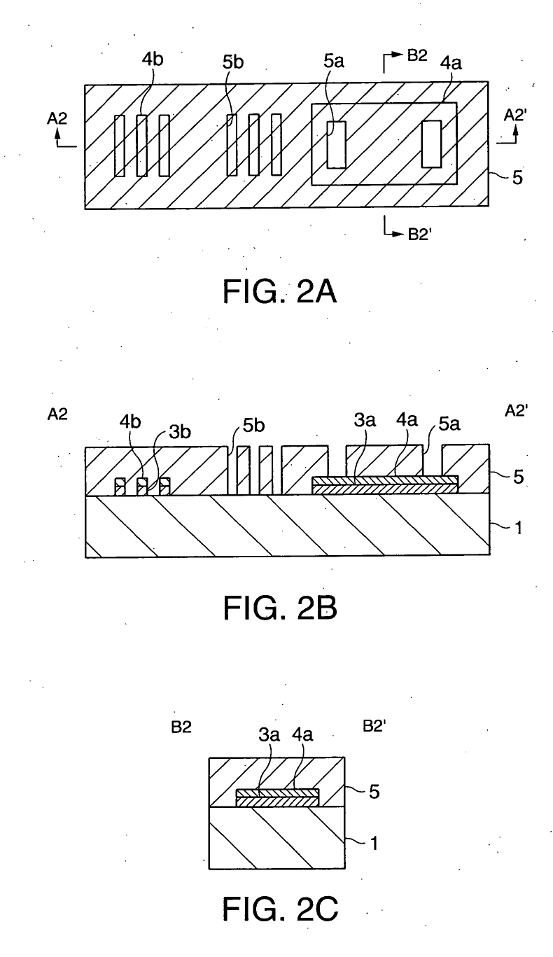

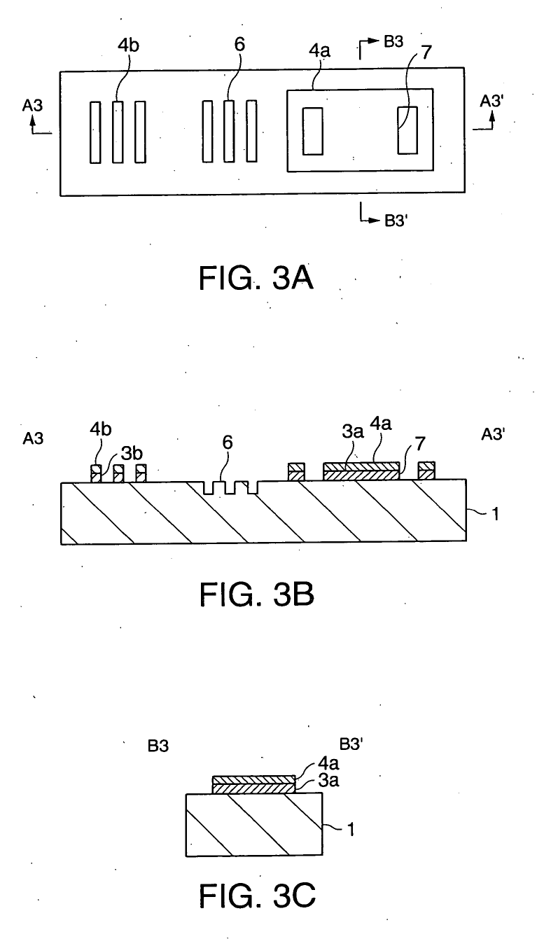

After the first semiconductor layers 3a, 3b and the second semiconductor layers 4a, 4b are formed, the oxide film 2 on the semiconductor substrate 1 is then removed as shown in FIG. 2. Subsequently, a resist pattern 5 having an opening 5a and an opening 5b is formed on the semiconductor substrate 1 by using the photolithography technique. The opening 5a is for exposing a part of the second semiconductor layer 4a in the SOI structure forming region R3. The opening 5b is for arranging a second alignment mark 6 shown in FIG. 3 in the alignment mark forming region R2. When the resist pattern 5 having the opening 5a and the opening 5b is formed on the semiconductor substrate 1, the alignment of the exposure mask can be carried out with reference to the position of a first alignment mark that is formed by the first semiconductor layer 3b and the second semiconductor layer 4b.

Next, an opening 7 is formed by etching the semiconductor substrate 1, the second semiconductor layer 4a and the first semiconductor layer 3a as using the resist pattern 5 as a mask as shown in FIG. 3. The opening 7 is for exposing a part of the semiconductor substrate 1 in the SOI structure forming region R3. At the same time, the second alignment mark 6 is formed in the alignment mark forming region R2. After the opening 7 is formed in the SOI structure forming region R3 and the second alignment mark 6 is formed in the alignment mark forming region R2, the resist pattern 5 is removed. In case of exposing the part of the semiconductor substrate 1, the etching may be stopped at the surface of the semiconductor substrate 1 or the semiconductor substrate 1 may be over-etched so as to form a concave portion in the semiconductor substrate 1. A position to arrange the opening 7 may correspond to a part of an device isolation region of the second semiconductor layer 4a.

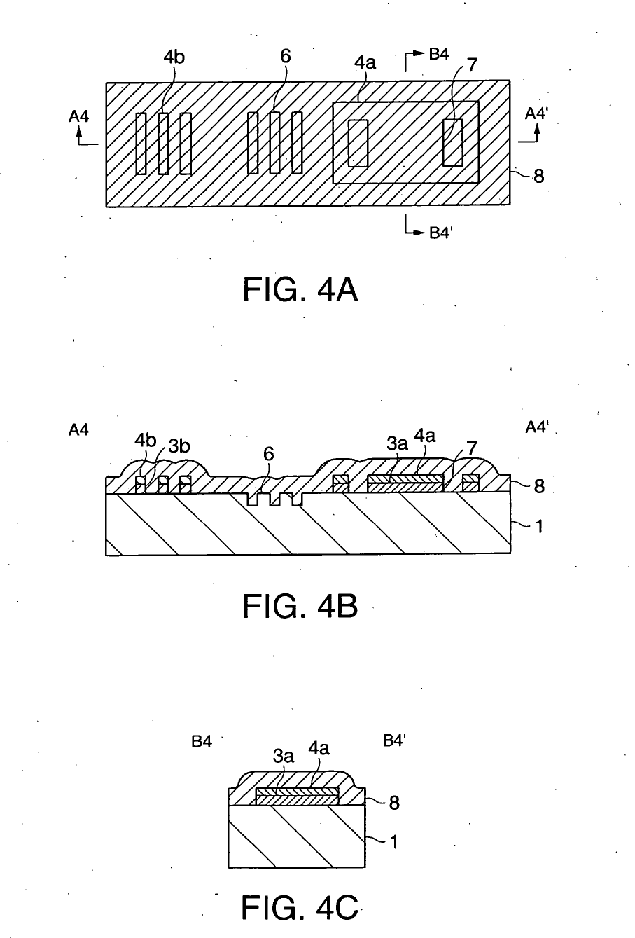

Next, a supporter 8 is formed on the whole top face of the semiconductor substrate 1 by the CVD and the like as shown in FIG. 4. The supporter 8 is also formed on the side walls of the first semiconductor layer 3a and the second semiconductor layer 4a in the opening 7. The supporter 8 supports the second semiconductor layer 4a on the semiconductor substrate 1. Insulating materials such as a silicon oxide film and a silicon nitride film can be used to form the supporter 8. Semiconductor such as polysilicon and single-crystalline silicon may also be used to form the supporter 8.

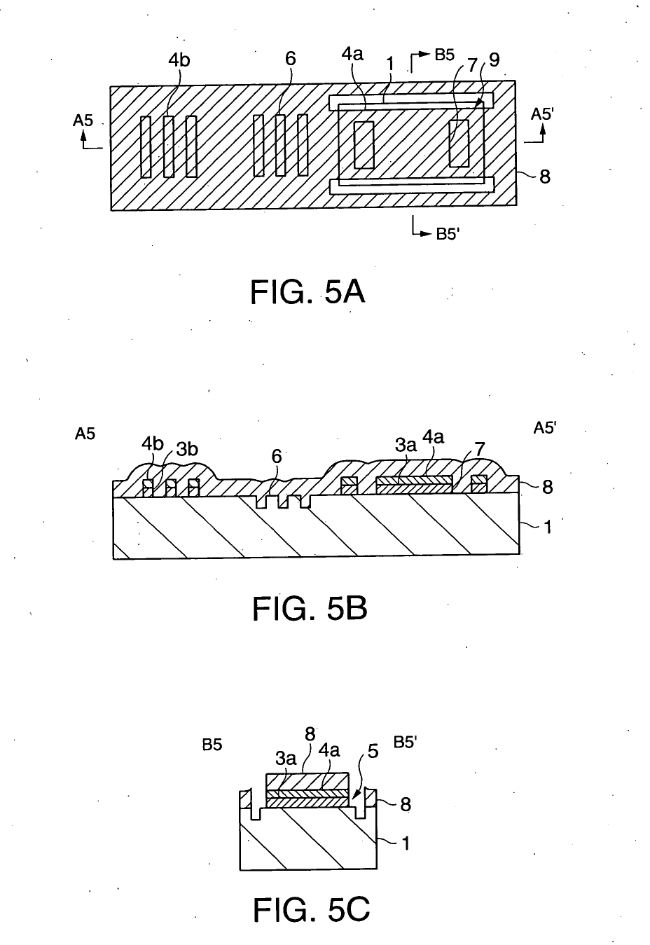

Next, an exposure face 9 which exposes a part of the first semiconductor layer 3a in the SOI structure forming region R3 is formed by patterning the supporter 8, the second semiconductor layer 4a and the first semiconductor layer 3a by using the photolithography or etching technique as shown in FIG. 5. When the exposure face 9 for exposing the part of the semiconductor layer 3a is formed, the exposure mask alignment in the photolithography can be carried out with reference to the position of the second alignment mark 6 which is formed in the second alignment mark forming region R2.

The position of the exposure face 9 may correspond to a part of the device isolation region of the second semiconductor layer 4a. In case of exposing the part of the first semiconductor layer 3a, the etching may be stopped at the surface of the first semiconductor layer 3a or the first semiconductor layer 3a may be over-etched so as to form a concave portion in the first semiconductor layer 3a. Alternatively, a hole that penetrates the first semiconductor layer 3a so as to expose the surface of the semiconductor substrate 1 may be formed in the first semiconductor layer 3a in which the exposure face 9 is formed. Here, if the etching of the first semiconductor layer 3a is stopped halfway, it can prevent the surface of the semiconductor substrate 1 in the SOI structure forming region R3 from being exposed. Accordingly, in case where the first semiconductor layer 3a is etched and removed, it is possible to shorten the time for exposing the semiconductor substrate 1 in the SOI structure forming region R3 to an etching solution or an etching gas. Therefore, it is possible to prevent the semiconductor substrate 1 in the SOI structure forming region R3 from being over-etched.

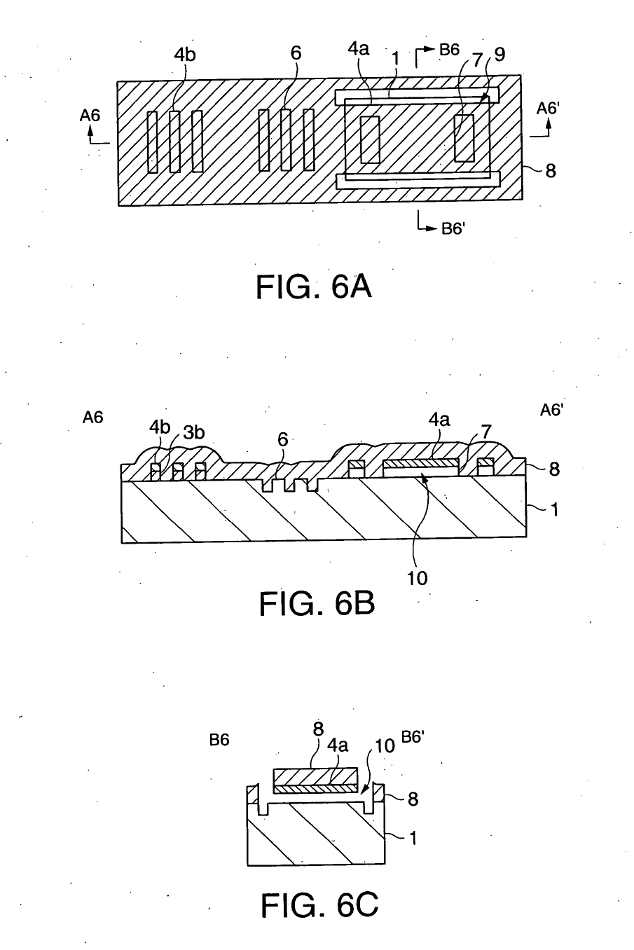

Next, the first semiconductor layer 3a is etched and removed by contacting the first semiconductor layer 3a with an etching gas or an etching solution through the exposure face 9 as shown in FIG. 6. In this way, a hollow part 10 is formed between the semiconductor substrate 1 and the second semiconductor layer 4a.

Here, if the supporter 8 is provided in the opening 7, the second semiconductor layer 4a can be supported on the semiconductor substrate 1 even when the first semiconductor layer 3a is removed. Furthermore, even when the second semiconductor layer 4a overlaps the first semiconductor layer 3a, if the exposure face 9 is provided separately from the opening 7, it is possible to make the first semiconductor layer 3a under the second semiconductor layer 4a contact with the etching gas or the etching solution.

Therefore, it is possible to place the second semiconductor layer 4a on the insulating material while reducing the chance of defects in the second semiconductor layer 4a. Accordingly, the isolation between the second semiconductor layer 4a and the semiconductor substrate 1 can be secured without impairing the quality of the second semiconductor layer 4a.

In case where the semiconductor substrate 1 and the second semiconductor layer 4a are made of Si and the first semiconductor layer 3a is made of SiGe, a fluoro nitric acid solution (mixture of hydrofluoric acid, nitric acid and water) is preferably used as the etching solution for the first semiconductor layer 3a. In this way, about 1:100-1000 of the selectivity between Si and SiGe can be obtained. This allows the first semiconductor layer 3a to be removed while preventing the semiconductor substrate 1 and the second semiconductor layer 4a from being over-etched. Fluoro nitric acid hydrogen peroxide water, ammonia hydrogen peroxide water, fluoro acetic acid hydrogen peroxide water and the like may also be used as the etching solution for the first semiconductor layer 3a.

Moreover, the first semiconductor layer 3a may be made porous by anodic oxidation and the like before the first semiconductor layer 3a is removed by the etching. The first semiconductor layer 3a may be made amorphous by performing ion implantation into the first semiconductor layer 3a. In this way, the etching rate of the first semiconductor layer 3a can be increased and this can increase the etching area of the first semiconductor layer 3a while preventing the second semiconductor layer 4a from being over-etched.

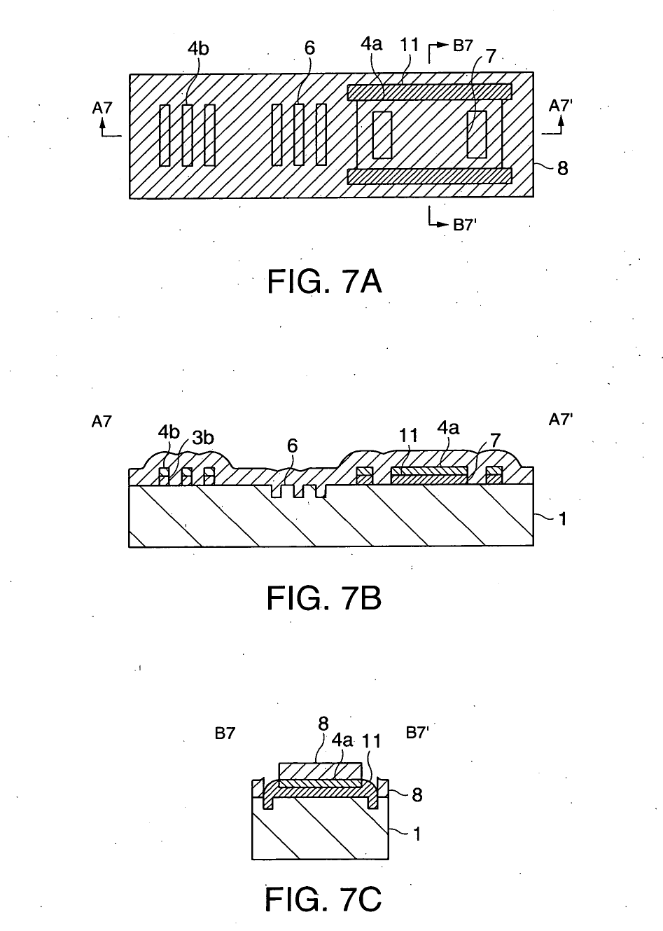

Next, a buried insulating layer 11 is formed in the hollow part 10 between the semiconductor substrate 1 and the second semiconductor layer 4a by thermally oxidizing the semiconductor substrate 1 and the second semiconductor layer 4a as shown in FIG. 7. After the buried insulating layer 11 is formed in the hollow part 10, high temperature anneal of higher than 1000° C. may be performed. In this way, it is possible to reflow the supporter 8 and the buried insulating layer 11 can be formed without leaving space around the buried insulating layer 11 since stress is applied to the second semiconductor layer 4a from above. The buried insulating layer 11 may be formed so as to fully fill the hollow part 10 or so as to leave a portion of the hollow part 10.

In the method shown in FIG. 7, though the buried insulating layer 11 was formed in the hollow part 10 between the semiconductor substrate 1 and the second semiconductor layer 4a by thermally oxidizing the semiconductor substrate 1 and the second semiconductor layer 4a, an insulating layer may be alternatively formed in the hollow part 10 between the semiconductor substrate 1 and the second semiconductor layer 4a by the CVD method and the buried insulating layer 11 is formed in the hollow part 10 between the semiconductor substrate 1 and the second semiconductor layer 4a. In this way, the hollow part 10 between the semiconductor substrate 1 and the second semiconductor layer 4a can be filled with the other material than an oxide film as well as preventing the film thickness of the second semiconductor layer 4a from being reduced. Accordingly, it is possible to increase the film thickness of the buried insulating layer 11 which is placed at the back side of the second semiconductor layer 4a. At the same time, it is possible to decrease the dielectric constant. This reduces parasitic capacitance at the back side of the second semiconductor layer 4a.

As the material for forming the buried insulating layer 11, besides the silicon oxide film, for example, there are a fluorinated silicate glass (FSG) film, a silicon nitride film and the like. In addition to a spin on glass (SOG) film, organic low-k films such as a phosphosilicate glass (PSG) film, a boro-phospho-silicate glass (BPSG) film, poly arylene ether (PAE) series films, hydrogen silsesquioxane (HSQ) series films, methyl silsesquioxane (MSQ) series films, PCB series films, CF series films, SiOC series films and SiOF series films can be used as the buried insulating layer 11. Alternatively, porous films of the above-mentioned films may also be used as the buried insulating layer 11.

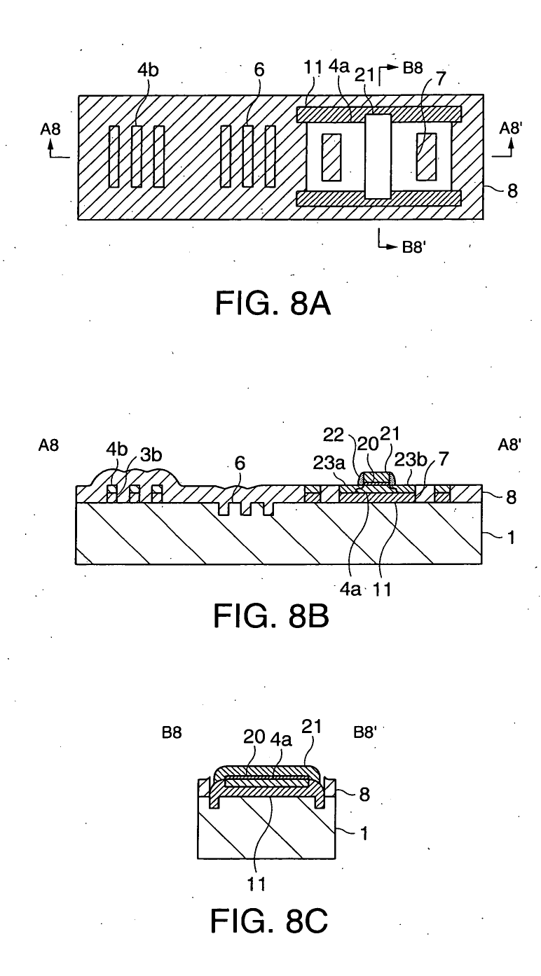

Next, the surface of the second semiconductor layer 4a in the SOI structure forming region R3 is exposed by etching the supporter 8 as shown in FIG. 8. The etching will be performed by using the photolithography technique or the etching technique in combination with an etch-back method or a chemical mechanical polishing (CMP) method if required.

Subsequently, the surface of the second semiconductor layer 4a is thermally oxidized and a gate insulating film 20 is formed on the surface of the second semiconductor layer 4a. Then, a polycrystalline silicon layer is formed on the second semiconductor layer 4a where the gate insulating film 20 is formed by a method such as the CVD. A gate electrode 21 is formed on the second semiconductor layer 4a by patterning the polycrystalline silicon layer by using the photolithography technique or the etching technique. When the gate electrode 21 is formed, alignment of the exposure mask in the photolithography can be carried out with reference to the position of the second alignment mark 6 which is formed in the second alignment mark forming region R2.

Next, a LDD layer which is lightly doped layer provided on the sides of the gate electrode 21 is formed in the second semiconductor layer 4a by ion implantation in which an impurity such as As, P and B is introduced into the second semiconductor layer 4a by using the gate electrode 21 as a mask. An insulating layer is then formed on the second semiconductor layer 4a where the LDD layer is formed by the CVD and the like. A side wall 22 is respectively formed on the side walls of the gate electrode 21 by etching back the insulating layer by using an anisotropic etching method such as reactive ion etching (RIE). Subsequently, a source/drain layer 23a, 23b which is a highly doped layer provided on the side of the side wall 22 is formed in the second semiconductor layer 4a by the ion implantation in which the impurity such as As, P and B is introduced into the second semiconductor layer 4a by using the gate electrode 21 and the side wall 22 as a mask.

In this way, it is possible to place the opening 7 in the SOI structure forming region R3 with reference to the position of the first alignment mark that specifies the position of the SOI structure forming region. R3. Accordingly, the opening 7 is precisely arranged in the SOI structure forming region R3. Furthermore, it is possible to arrange the exposure face 9 with reference to the position of the second alignment mark 6 that specifies the position of the opening 7. Thereby, the exposure face 9 can be accurately arranged against the opening 7. In addition, the device can be further formed with reference to the position of the second alignment mark 6 as a reference point of the alignment in the later processes. Therefore, even after the SOI structure forming region R3 is formed, the device can be arranged in the SOI structure forming region R3 without referring the first alignment mark that specifies the position of the SOI structure forming region R1. Consequently, the accuracy of the device alignment is improved.

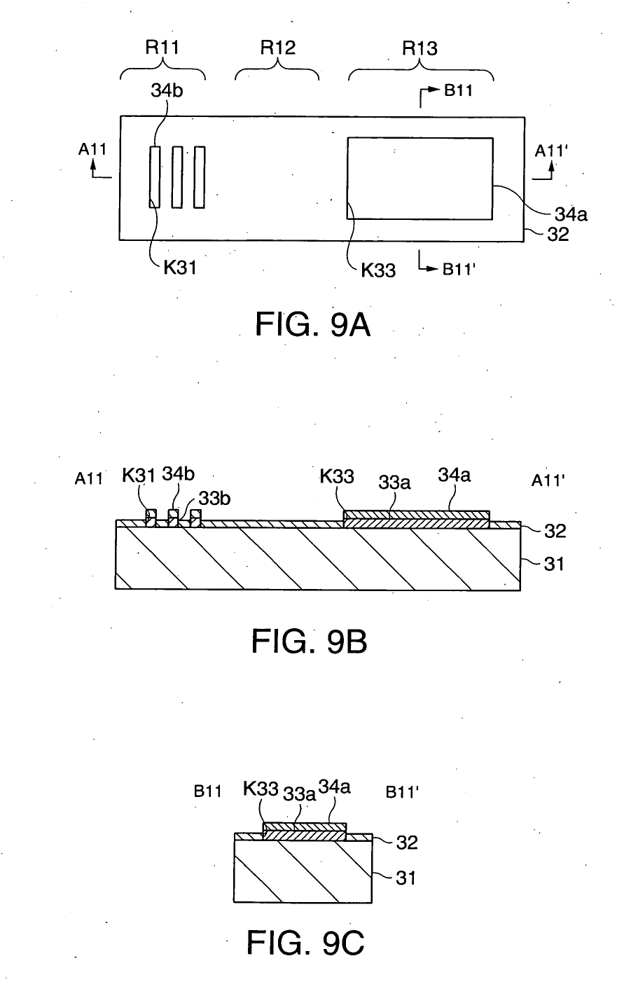

FIGS. 9A to 13A are plan views showing a method of manufacturing a semiconductor device according to a second embodiment of the invention. FIGS. 9B to 13B are sectional views along the lines A11 to A11′ through A15 to A15′ in FIGS. 9A to 13A. FIGS. 9C to 13C are sectional views along the lines B11 to B11′ through B15 to B15′ in FIGS. 9A to 13A.

As shown in FIG. 9, a first alignment mark forming region R11 for making the first alignment mark, a second alignment mark forming region R12 for making the second alignment mark and a SOI structure forming region R13 for making the SOI structure are provided on a semiconductor substrate 31. An oxide film 32 is formed on the whole surface of the semiconductor substrate 31 by an oxidation method such as the thermal oxidation. An opening K31 for arranging the first alignment mark in the first alignment mark forming region R11 is formed by patterning the oxide film 32 by using the photolithography or etching technique. At the same time, an opening K33 for disposing the SOI structure in the SOI structure forming region R13 is also formed by patterning the oxide film 32. Subsequently, a first semiconductor layer 33a and a second semiconductor layer 34a are sequentially formed in the SOI structure forming region R13 by the selective epitaxial growth. At the same time, a first semiconductor layer 33b and a second semiconductor layer 34b are sequentially formed in the first alignment mark forming region R11.

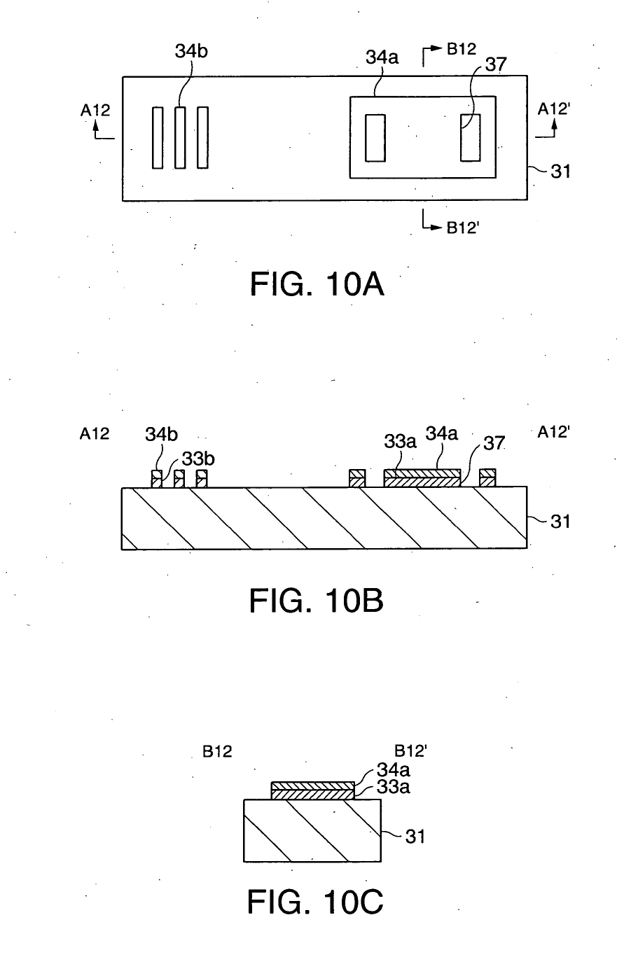

After the first semiconductor layers 33a, 33b and the second semiconductor layers 34a, 34b are formed, the oxide film 32 on the semiconductor substrate 31 is removed as shown in FIG. 10. Subsequently, an opening 37 is formed by patterning the second semiconductor layers 34a and the first semiconductor layer 33a as using the photo lithography or etching technique. The opening 37 is for exposing a part of the semiconductor substrate 31 in the SOI structure forming region R13. When the opening 37 for exposing a part of the semiconductor substrate 31 is formed, alignment of the exposure mask used in the photolithography can be carried out with reference to the position of the first alignment mark which is formed by the first semiconductor layer 33b and the second semiconductor layer 34b.

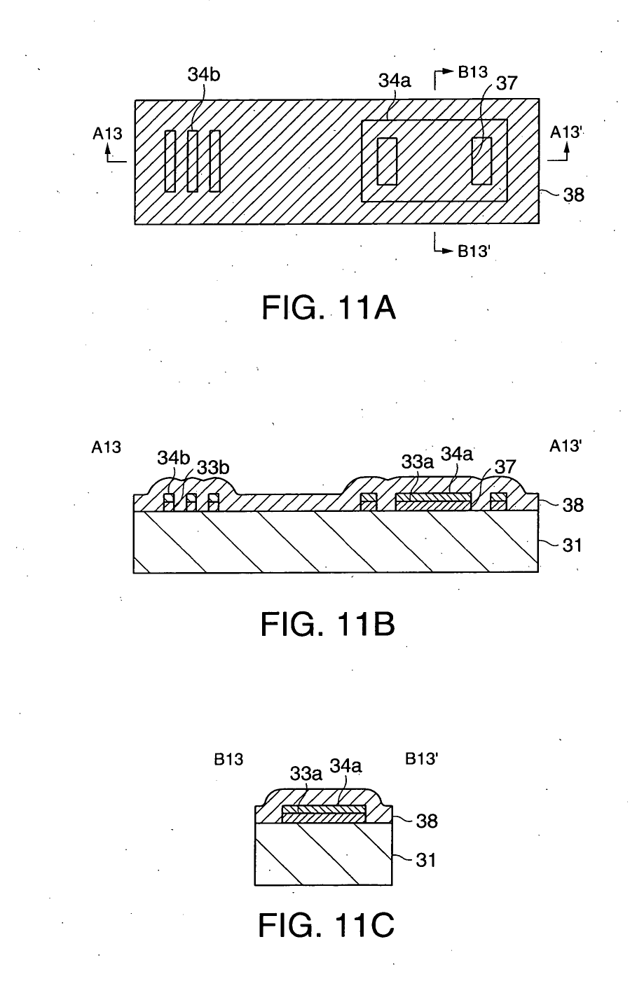

Next, a supporter 38 is formed on the whole face of the semiconductor substrate 31 by the CVD and the like as shown in FIG. 11. The supporter 38 is also formed on the side walls of the first semiconductor layer 33a and the second semiconductor layer 34a in the opening 37. The supporter 38 supports the second semiconductor layer 34a on the semiconductor substrate 31.

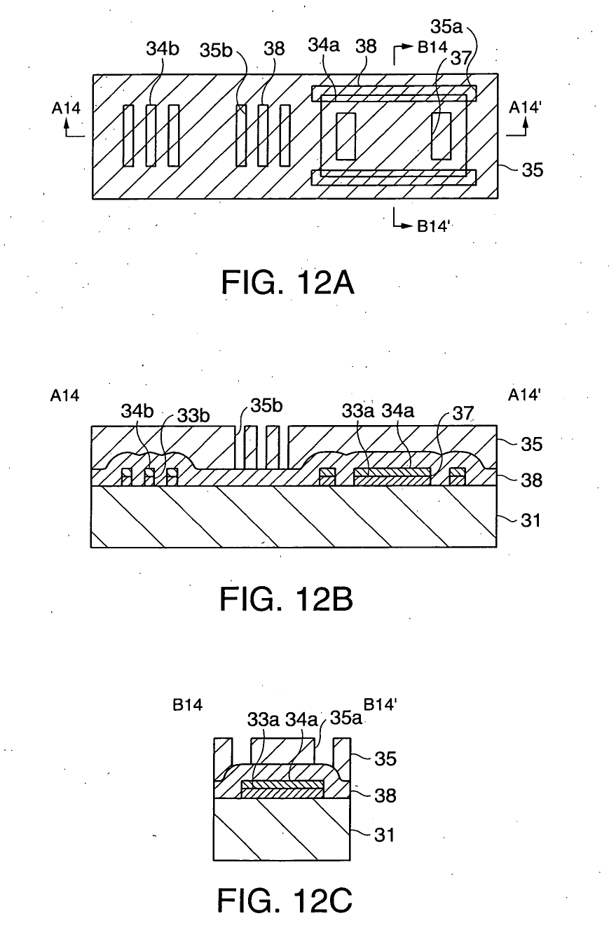

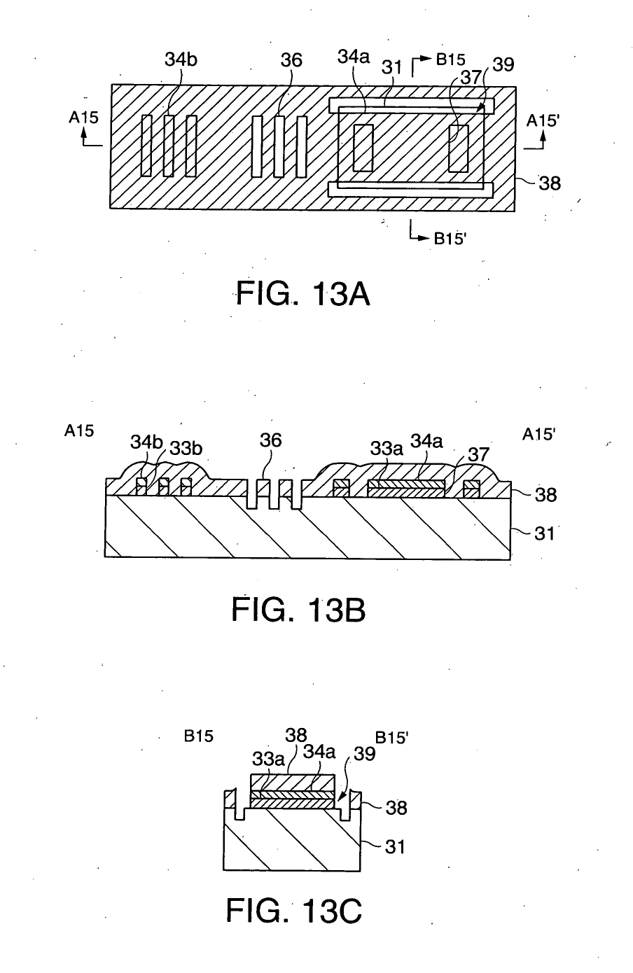

Next, a resist pattern 35 having an opening 35a and an opening 35b is formed on the semiconductor substrate 31 by using the photolithography or etching technique as shown in FIG. 12. The opening 35a is for exposing a part of the second semiconductor layer 14a in the SOI structure forming region R13. The opening 35b is for arranging a second alignment mark 36 shown in FIG. 13 in the second alignment mark forming region R12. When the resist pattern 35 having the opening 35a and the opening 35b is formed on the semiconductor substrate 31, the alignment of the exposure mask can be carried out with reference to the position of the first alignment mark that is formed by the first semiconductor layer 33b and the second semiconductor layer 34b.

Next, an exposure face 39 which is for exposing a part of the first semiconductor layer 33a in the SOI structure forming region R13 is formed by etching the supporter 38, the semiconductor substrate 31, the second semiconductor layer 34a and the first semiconductor layer 33a by using the resist pattern 35 as a mask as shown in FIG. 13. At the same time, the second alignment mark 36 is formed in the alignment mark forming region R12. After the opening 37 is formed in the SOI structure forming region R13 and the second alignment mark 36 is formed in the alignment mark forming region R12, the resist pattern 35 is removed.

Next, the first semiconductor layer 33 a under the second semiconductor layer 34a is removed and the buried insulating layer is formed under the second semiconductor layer 34a through the same processes shown in FIGS. 6-8. In this way, a device such as a transistor can be formed in the second semiconductor layer 34a.

According to the above-described way, it is possible to place the opening 37 and the exposure face 39 in the SOI structure forming region R13 with reference to the position of the first alignment mark that specifies the position of the SOI structure forming region R13. Accordingly, the opening 37 and the exposure face 39 are precisely arranged in the SOI structure forming region R13. Furthermore, the device can be further formed as referring to the position of the second alignment mark 36 that specifies the position of the exposure face 39 as a reference point of the alignment in the later processes. Therefore, even after the SOI structure forming region R13 is formed, the device can be arranged in the SOI structure forming region R13 without referring the first alignment mark that specifies the position of the SOI structure forming region R13. Consequently, the accuracy of the device alignment is improved.

In the embodiments described above, the second alignment mark 6 specifying the position of the opening 7 is formed with reference to the first alignment mark that specifies the position of the SOI structure forming region R3, and the second alignment mark 36 specifying the position of the exposure face 39 is formed with reference to the first alignment mark that specifies the position of the SOI structure forming region R13. However, the second alignment mark 6 specifying the position of the opening 7 is formed with reference to the first alignment mark that specifies the position of the SOI structure forming region R3, then a third alignment mark specifying the position of the exposure face 9 may be formed with reference to the second alignment mark 6 that specifies the position of the opening 7.

Furthermore, a SOI transistor may be formed in the SOI structure forming region R3, R13 and the bulk transistor may be formed in the semiconductor substrate 1, 31. In this way, both the SOI structure and the bulk structure can be formed on the same semiconductor substrate 1, 31 without using the SOI substrate. This can prevent cost increase and allows that both the SOI transistor and a transistor with a high withstand voltage are mounted on the one semiconductor substrate 1, 31.

The entire disclosure of Japanese Patent Application No. 2005-094775, filed Mar. 29, 2005 is expressly incorporated by reference herein.

What is claimed is:

1. A method of manufacturing a semiconductor device, comprising:
forming an insulating film on a semiconductor substrate;
removing the insulating film selectively in a first alignment mark forming region and a silicon-on-insulator (SOI) structure forming region that are provided on the semiconductor substrate by patterning the insulating film;
forming a first semiconductor layer selectively in the first alignment mark forming region and the SOI structure forming region by epitaxial growth;
forming a second semiconductor layer whose etching rate is smaller than an etching rate of the first semiconductor layer selectively on the first semiconductor layer by the epitaxial growth;
removing the insulating film on the semiconductor substrate after the second semiconductor layer is formed;
forming a first exposure part and a second alignment mark by selectively etching the second semiconductor layer, the first semiconductor layer and the semiconductor substrate as referring the position of the second semiconductor layer in the first alignment mark forming region as a first alignment mark for arrangement, the first exposure part penetrating the second semiconductor layer and the first semiconductor layer so as to expose the semiconductor substrate, and the second alignment mark being formed in a second alignment mark forming region on the semiconductor substrate;
forming a supporter made of a material with a smaller etching rate than the etching rate of the first semiconductor layer, the supporter supporting the second semiconductor layer on the semiconductor substrate through the first exposure part;
forming a second exposure part by referring the second alignment mark as a reference point for arrangement after the supporter is formed, the second exposure part exposing the first semiconductor layer;
forming a hollow part between the semiconductor substrate and the second semiconductor layer by selectively etching the first semiconductor layer through the second exposure part, the hollow part being made by removing the first semiconductor layer;
forming a buried insulating layer that fills the hollow part;
forming a first gate electrode by referring the second alignment mark as the reference point for arrangement, the first gate electrode being provided on the second semiconductor layer through a first gate insulating film; and
forming a first source/drain layer that is arranged so as to hold the first gate electrode therebetween in the second semiconductor layer.

2. A method of manufacturing a semiconductor device, comprising:
forming an insulating film on a semiconductor substrate;
removing the insulating film selectively in a first alignment mark forming region and a silicon-on-insulator (SOI) structure forming region that are provided on the semiconductor substrate by patterning the insulating film;
forming a first semiconductor layer selectively in the first alignment mark forming region and the SOI structure forming region by epitaxial growth;
forming a second semiconductor layer whose etching rate is smaller than an etching rate of the first semiconductor layer selectively on the first semiconductor layer by the epitaxial growth;
removing the insulating film on the semiconductor substrate after the second semiconductor layer is formed;
forming a first exposure part by selectively etching the second semiconductor layer in the SOI structure forming region, the first semiconductor layer and the semiconductor substrate, the first exposure part penetrating the second semiconductor layer and the first semiconductor layer so as to expose the semiconductor substrate;
forming a supporter made of a material with a smaller etching rate than the etching rate of the first semiconductor layer, the supporter supporting the second semiconductor layer on the semiconductor substrate through the first exposure part;
forming a second exposure part and a second alignment mark by selectively etching the supporter, the second semiconductor layer, the first semiconductor layer and the semiconductor substrate as referring the position of the second semiconductor layer in the first alignment mark forming region as a first alignment mark for arrangement after the supporter is formed, the second exposure part exposing the first semiconductor layer, and the second alignment mark being formed in a second alignment mark forming region on the semiconductor substrate;
forming a hollow part between the semiconductor substrate and the second semiconductor layer by selectively etching the first semiconductor layer through the second exposure part, the hollow part being made by removing the first semiconductor layer;
forming a buried insulating layer that fills the hollow part;
forming a first gate electrode by referring the second alignment mark as the reference point for arrangement, the first gate electrode being provided on the second semiconductor layer through a first gate insulating film; and
forming a first source/drain layer that is arranged so as to hold the first gate electrode therebetween in the second semiconductor layer.

3. A method of manufacturing a semiconductor device, comprising:
forming an insulating film on a semiconductor substrate;
removing the insulating film selectively in a first alignment mark forming region and a silicon-on-insulator (SOI) structure forming region that are provided on the semiconductor substrate by patterning the insulating film;
forming a first semiconductor layer selectively in the first alignment mark forming region and the SOI structure forming region by epitaxial growth;
forming a second semiconductor layer whose etching rate is smaller than an etching rate of the first semiconductor layer selectively on the first semiconductor layer by the epitaxial growth;
removing the insulating film on the semiconductor substrate after the second semiconductor layer is formed;
forming a first exposure part and a second alignment mark by selectively etching the second semiconductor layer, the first semiconductor layer and the semiconductor substrate as referring the position of the second semiconductor layer in the first alignment mark forming region as a first alignment mark for arrangement, the first exposure part penetrating the second semiconductor layer and the first semiconductor layer so as to expose the semiconductor substrate, and the second alignment mark being formed in a second alignment mark forming region on the semiconductor substrate;
forming a supporter made of a material with a smaller etching rate than the etching rate of the first semiconductor layer, the supporter supporting the second semiconductor layer on the semiconductor substrate through the first exposure part;
forming a second exposure part and a third alignment mark by selectively etching the supporter, the second semiconductor layer, the first semiconductor layer and the semiconductor substrate as referring the position of the second alignment mark for arrangement after the supporter is formed, the second exposure part exposing the first semiconductor layer, and the third alignment mark being formed in a third alignment mark forming region on the semiconductor substrate;
forming a hollow part between the semiconductor substrate and the second semiconductor layer by selectively etching the first semiconductor layer through the second exposure part, the hollow part being made by removing the first semiconductor layer;
forming a buried insulating layer that fills the hollow part;
forming a first gate electrode by referring the third alignment mark as the reference point for arrangement, the first gate electrode being provided on the second semiconductor layer through a first gate insulating film; and
forming a first source/drain layer that is arranged so as to hold the first gate electrode therebetween in the second semiconductor layer.

4. The method of manufacturing a semiconductor device according to claim 1, further comprising:
forming a second gate electrode in a bulk structure forming region on the semiconductor substrate through a second gate insulating film; and
forming a second source/drain layer that is arranged so as to hold the second gate electrode therebetween in the second semiconductor layer.
